(19) United States
(12) Patent Application Publication
(10) Pub. No.: US 2005/0101136 A1
(43) Pub. Date: May 12, 2005

(54) Etching method and method of manufacturing circuit device using the same

(76) Inventor: Shinya Mori, Saitama (JP)

Correspondence Address: FISH & RICHARDSON P.C., CITIGROUP CENTER 52ND FLOOR, 153 EAST 53RD STREET, NEW YORK, NY, 10022-4611, US

(21) Appl. No.: 10/928,900

(22) Filed: Aug. 27, 2004

(30) Foreign Application Priority Data
Sep. 2, 2003 (JP) P. 2003-310764

(51) Int. Cl. H01L 21/461

(52) U.S. Cl. 438/689

(57) ABSTRACT

Provided are an etching method capable of improving an etching factor, and a method of manufacturing a circuit device using the etching method. In the etching method, an etching resist is firstly coated on a surface of a conductive foil as an etching target material. Then, the etching resist is subjected to selective exposure by use of an exposure mask, thereby selectively transforming the etching resist. In this way, a non-exposed region is formed as a remaining region having a cross section, in which a lower part thereof is greater than an upper part thereof. Thereafter, the etching resist in a region other than the remaining region is removed by use of a solution, and the conductive foil is subjected to etching by use of the remaining region as a mask.

### BACKGROUND OF THE INVENTION

1. Field of the Invention

The present invention relates to an etching method and a method of manufacturing a circuit device using the same. More specifically, the present invention relates to an etching method capable of improving an etching factor, and to a method of manufacturing a circuit device using the same.

2. Description of the Related Art

A conventional etching method will be described with reference to FIGS. 11A to 11E.

Referring to FIG. 11A, a conductive foil 101 is formed on a surface of a board 102. Further, an etching resist 100 is coated so as to cover a surface of the conductive foil 101.

Referring to FIG. 11B, the resist 100 is selectively exposed through an exposure mask (not shown). Here, the resist 100 is a negative resist, and the resist 100 corresponding to a region to be left as a conductive pattern is selectively irradiated with a light beam 104.

Referring to FIG. 11C, by melting with an agent, the resist 100 in a region other than the position which was irradiated with the light beam in the precedent process is selectively peeled off. Then, referring to FIG. 11D, etching is performed by use of the remaining resist 100 as a mask. As a result, a conductive pattern 103 is formed by selectively removing the conductive foil 101. Here, wet etching is adopted so as to cause etching to progress almost isotropically. Therefore, a cross section of the conductive pattern 103 is formed into a tapered shape.

Referring to FIG. 11E, an etching factor will be described. Here, a dimension between a position where a side surface of the conductive pattern 103 is eroded most inward and an upper side edge of the resist will be defined as a1. Meanwhile, a depth of the conductive foil 101 eroded in a vertical direction (that is, a thickness of the conductive pattern 103 herein) will be defined as t. Under such conditions, an etching factor Ef is expressed by (Ef=t/a1). In other words, a large value of this etching factor means a small side etching amount of an etching target material, and thereby means a possibility of fine processing. Such an etching method is applied to a manufacturing method for a printed board, a circuit device or the like.

However, the above-described etching method had a problem with small etching factor value. That is, erosion in a side direction by etching is significant, whereby a cross section of a conductive pattern is formed into a shape spreading toward a bottom. Such a phenomenon has inhibited fine processing of conductive patterns. In addition, there has been also a problem that a cross section of a conductive pattern was formed small and a current capacity was thereby reduced.

### SUMMARY OF THE PRESENT INVENTION

The present invention has been made in consideration of the foregoing problems. It is a principal object of the present invention to provide an etching method capable of improving an etching factor and a method of manufacturing a circuit device using the same.

An etching method of the present invention includes the forming an etching resist on a surface of an etching target material, forming a remaining region having a cross section in which a lower part is greater than an upper part by subjecting the etching resist to selective exposure using an exposure mask and thereby selectively transforming the etching resist, removing the etching resist other than the remaining region by use of a solution, and etching the etching target material by use of the remaining region as a mask.

A method of manufacturing a circuit device of the present invention includes preparing a conductive foil; forming an etching resist on a surface of the conductive foil; forming a remaining region having a cross section in which a lower part is greater than an upper part by subjecting the etching resist to selective exposure using an exposure mask and thereby selectively transforming the etching resist; removing the etching resist other than the remaining region by use of a solution; forming a conductive pattern by etching the conductive foil using the remaining region as a mask; disposing a circuit element on the conductive pattern; and forming sealing resin so as to cover the circuit element.

### BRIEF DESCRIPTION OF THE DRAWINGS

FIG. 1 is a flowchart showing an etching method of a preferred embodiment.

FIGS. 2A to 2C are cross-sectional views showing the etching method of the preferred embodiment.

FIGS. 3A to 3C are cross-sectional views showing the etching method of the preferred embodiment.

FIGS. 4A to 4C are cross-sectional views showing the etching method of the preferred embodiment.

FIGS. 5A to 5C are cross-sectional views showing a method of manufacturing a circuit device of another preferred embodiment.

FIGS. 6A to 6C are cross-sectional views showing the method of manufacturing a circuit device of the preferred embodiment.

FIGS. 7A to 7C are cross-sectional views showing the method of manufacturing a circuit device of the preferred embodiment.

FIGS. 8A to 8D are cross-sectional views showing the method of manufacturing a circuit device of the preferred embodiment.

FIGS. 9A to 9D are cross-sectional views showing the method of manufacturing a circuit device of the preferred embodiment.

FIGS. 10A and 10B are cross-sectional views showing the method of manufacturing a circuit device of the preferred embodiment.

FIGS. 11A to 11E are cross-sectional views showing a conventional etching method.

### DETAILED DESCRIPTION OF THE PREFERRED EMBODIMENTS

(First Embodiment for Describing an Etching Method)

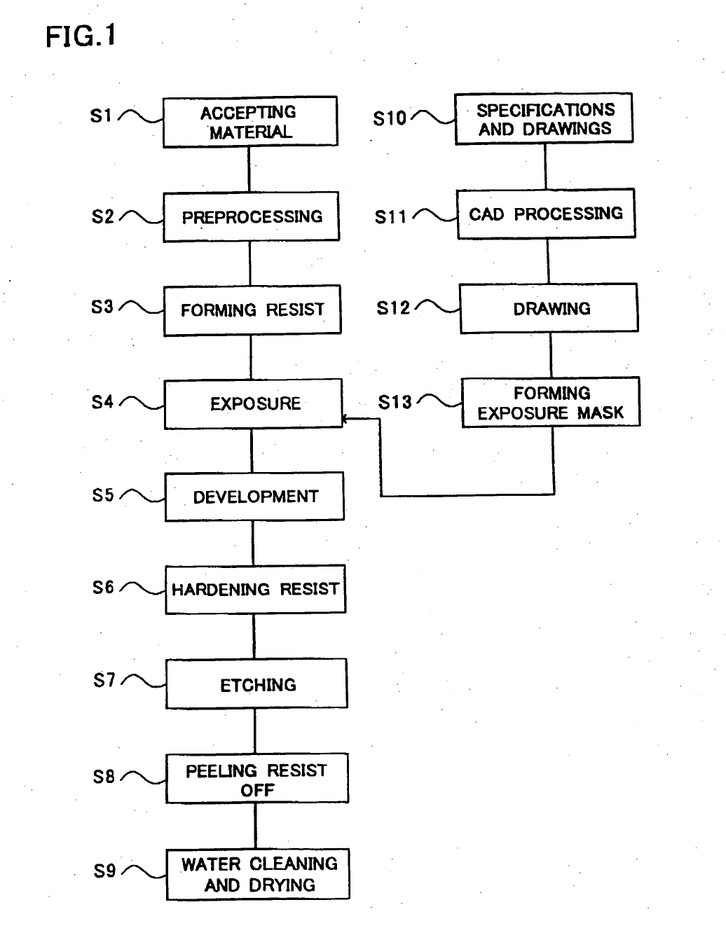

Firstly, an outline of an etching method of a preferred embodiment will be described with reference to a flowchart of FIG. 1.

First, in Step S1, an etching material subject to etching (an etching target material) is accepted. The material to be accepted herein may include a sheet of conductive foil made of metal, a laminated sheet in which a plurality of sheets of conductive foil are laminated with an insulating layer therebetween, a board applying a conductive foil on a surface thereof, and the like. Then, in Step S2, dust and oily components attached to a surface of the etching target material are removed as preprocessing.

In Step S3, a resist is formed on the surface of the etching target material. This resist can be formed by means of coating a liquid resist or laminating a resist of a sheet type (DFR). The resist used herein is either a negative resist or a positive resist. In Step 4, the coated resist is subjected to selective exposure. Then, in Step S5, the resist is subjected to selective etching by use of an etchant. Thereafter, the resist is cured in Step S6. Here, it is also possible to constitute the preferred embodiment of the present invention while omitting Step S6 for hardening the resist.

In Step S7, the etching target material is etched by use of an etching solution while utilizing the remaining resist as an etching mask. Then, the resist is peeled off by use of a solution in Step S8, and the etching target material is cleaned by water and then dried in Step S9. In this way, the etching process is completed. Here, it is also possible to carry out Step S9 simultaneously in combination with Step S8.

Illustration shown on a right side in the flowchart is a flowchart for showing a process of manufacturing an exposure mask used in the above-described Step S4. In Step S10, user specifications and drawings are obtained to design an electric circuit. In Step S11, a conductive pattern based on the electric circuit is designed by use of computer aided design (CAD) and the like. In Step S12, the conductive pattern is drawn by use of a lithography apparatus. In Step S13, the exposure mask is formed such that light is transmitted through a region corresponding to the conductive pattern or a region excluding the conductive pattern.

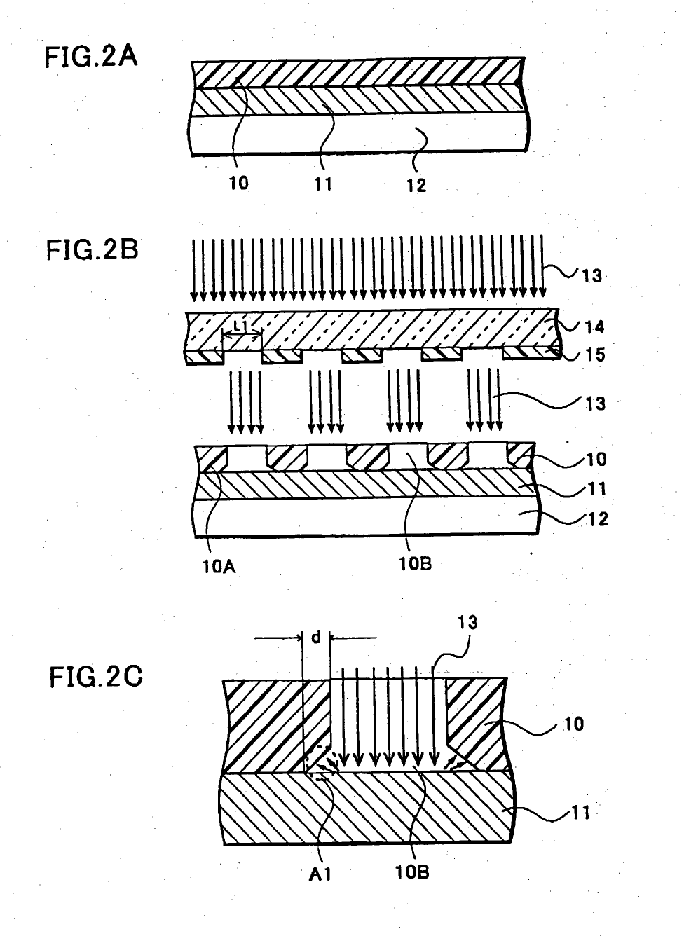

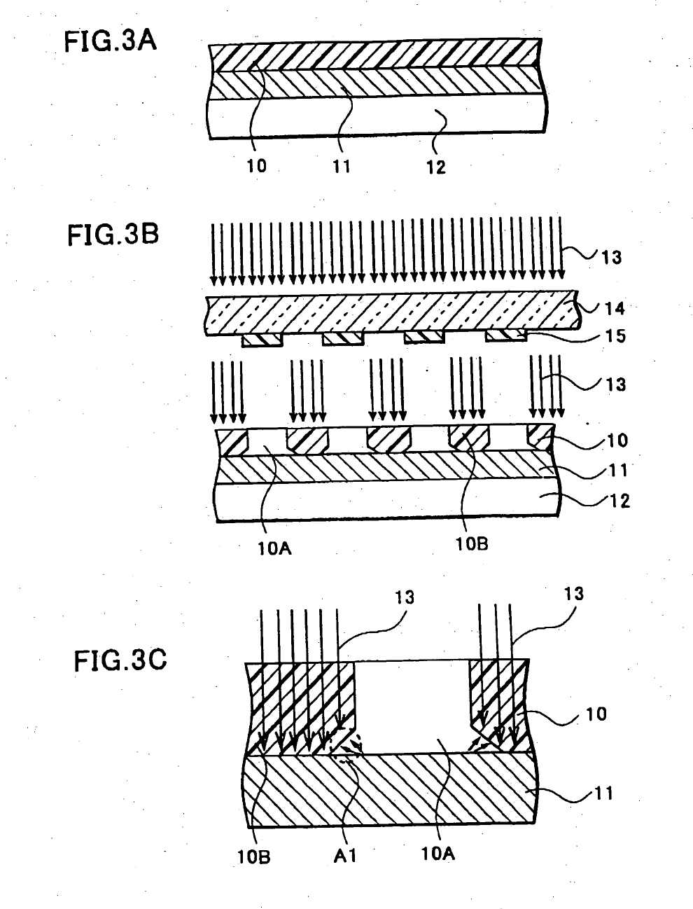

The outline of the etching process of the preferred embodiment has been described. Now, the process of patterning the etching resist (Step S5 to Step S6) will be described in detail with reference to FIG. 2A to FIG. 4C. Firstly, the process of subjecting the etching resist to exposure will be described with reference to FIG. 2A to FIG. 3C.

A method of performing exposure of a resist 10 which is a negative resist will be described with reference to FIGS. 2A to 2C. The negative resist is made of a material which is originally soluble in an alkali solution, and has a property that a portion irradiated with a light beam becomes insoluble therein.

Referring to FIG. 2A, a conductive foil 11 as an etching target material is formed on a surface of a board 12, and the resist 10 is coated on a surface of the conductive foil 11. Here, the negative resist is applied as the resist 10. Here, it is also possible to apply a positive resist instead of the negative resist.

Referring to FIG. 2B, the resist 10 is subjected to selective exposure by use of an exposure mask 14. To be more precise, the resist 10 corresponding to the region to be left as the conductive pattern is subjected to exposure and the other region is shielded. That is, an exposed region 10B of the resist 10 will remain and a non-exposed region 10A will be removed in a developing process. As for a concrete method of removing the non-exposed region 10A, the non-exposed region 10A is firstly swollen by soaking the resist 10 in a developing solution. Then, the swollen non-exposed region 10A is removed by use of water pressure.

The exposure mask 14 includes glass as a base material and an exposure pattern 15 formed on a surface of this glass. Here, it is also possible to adopt a film sheet made of resin and the like as the base material. The exposure pattern 15 is formed so as to correspond to the region to be selectively peeled off. Therefore, by irradiating the resist 10 with a light beam 13 from above through the above-described exposure mask 14 placed thereon, it is possible to selectively irradiate only the resist 10 in the region to be formed into the conductive pattern with the light beam 13. Here, an interval between lines in the exposure pattern will be defined as L1.

FIG. 2C is an enlarged view of FIG. 2B which shows a concrete cross-sectional shape of the exposed region 10B. A part of the light beam 13 with which the exposed region 10B of the resist 10 is irradiated passes through the resist 10 and reaches the surface of the conductive foil 11. Then, the light beam 13 is reflected by the surface of the conductive foil 11. Particularly, in a region A1 which is a peripheral portion of the exposed region 10B, the light beam 13 is reflected obliquely upward to the outside. The region A1 is also exposed by a reflected component of the light beam 13. Therefore, a cross section of the exposed region 10B is formed into a shape spreading toward a bottom, i.e. a lower part thereof is greater than an upper part thereof. In other words, the cross section of the exposed region 10B has a length of a lower bottom which is longer than a length of an upper bottom.

A concrete method of subjecting the region A1 to exposure includes a method of increasing intensity of the light beam 13 so as to increase the component passing through the resist 10. By use of this method, it is possible to allow more components of the light beam 13 to pass through the resist 10 which are reflected by the surface of the conductive foil 11, and thereby to subject the region A1 to exposure. Alternatively, it is possible to achieve a similar effect by adopting a material having large transparency with respect to the light beam 13 as the resist 10.

Next, the detailed exposure method adopting the resist 10, which is a positive resist, will be described with reference to FIGS. 3A to 3C. The positive resist is made of a material which is originally insoluble in a developing solution, and has a property that an exposed portion is transformed to be soluble in the developing solution.

Referring to FIG. 3A, the positive resist 10 is coated on the surface of the conductive foil 11 which is formed on the surface of the board 12.

Referring to FIG. 3B, the resist 10 is subjected to exposure by use of the exposure mask 14. Although the region of the resist 10 to be left over is exposed in the explanation concerning FIG. 2B, the region of the resist 10 to be removed is exposed herein. That is, the region of the resist 10 where the conductive pattern is not formed is subjected to exposure and transformation. Accordingly, on the exposure mask 14, there is formed the exposure pattern 15 in the same shape as the conductive pattern subject to formation.

Referring to FIG. 3C, the non-exposed region 10A will be described in detail. Here, the non-exposed region 10A which is not irradiated with the light beam 13 will remain as the etching mask. Accordingly, the region of the resist 10 to be partially removed (the exposed region 10B) is irradiated with the light beam 13. In the periphery of the exposed region 10B, the light beam 13 does not reach the bottom of the resist 10. That is, the bottom in the periphery of the exposed region 10B is not exposed and thus not transformed. Therefore, the cross-sectional shape of the non-exposed region 10A is formed into the same shape as the exposed region 10B shown in FIG. 2C. That is, in the cross section of the non-exposed region 10A, the lower part is greater than the upper part.

To be more precise, a method of not exposing the region A1 includes a method of decreasing an amount of irradiation with the light beam 13. In this way, irradiation with the light beam 13 is reduced particularly in the periphery of the exposed region 10B and it is thereby possible to decrease the amount of the light beam 13 reaching the region A1. Another method is a method of increasing a light shielding property of the resist 10. This method can also exhibit the above-described effect. It is also possible to exhibit the above-described effect by shortening exposure time.

In the above explanations, the methods of forming the resist having the cross-sectional shape spreading toward the bottom by mainly controlling the exposure conditions have been described. However, it is also possible to form the resist having the cross-sectional shape spreading toward the bottom by changing other etching conditions. Other conceivable methods may include a first method of changing the concentration of the developing solution, and a second method of changing the type of the developing solution.

To be more precise, the first method of changing the concentration of the developing solution is a method of increasing the concentration of the developing solution for use in development of the resist 10 as compared to a usual case. In a usual case, the developing solution may be a solution prepared by dissolving 1% of sodium carbonate (NaCO3) in purified water, or a solution prepared by dissolving 1% of an organic amine in purified water. By increasing the concentration, it is possible to promote rapid melting or swelling of the resist 10. Accordingly, it is possible to form the cross-sectional shape of the remaining resist 10 into the cross-sectional shape spreading toward the bottom.

The second method of changing the type of the developing solution is a method of using solution of an organic amine instead of sodium carbonate. Aqueous solution of organic amine possesses stronger attack than aqueous solution of sodium carbonate. Accordingly, it is possible to form the cross-sectional shape of the resist 10 into the cross-sectional shape spreading toward the bottom.

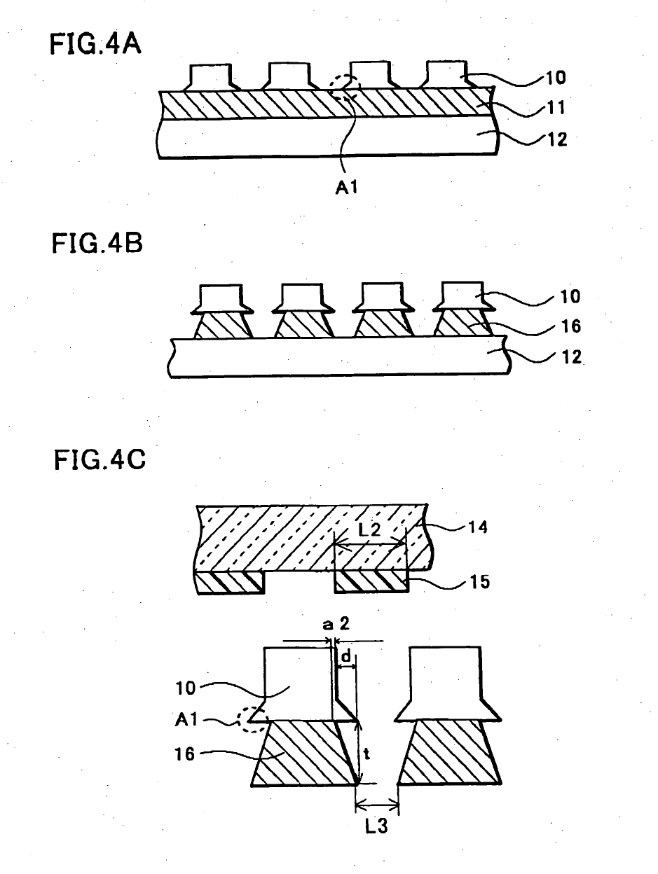

The developing process and subsequent processes will be described in detail with reference to FIGS. 4A to 4C.

Referring to FIG. 4A, the resist 10 is patterned by performing development. To be more precise, by developing the exposed resist 10, the resist 10 in the region corresponding to the conductive pattern subject to formation is left and the resist 10 in the other region is removed. This can be performed by soaking the resist 10 in an alkaline solution. Accordingly, the exposed region 10B is left in the resist 10 shown in FIG. 2B, while the non-exposed region 10A is left in the resist 10 shown in FIG. 3B.

Referring to FIG. 4B, subsequently, a pattern 16 is formed by etching the conductive foil 11 using the remaining resist 10 as an etching mask. Here, the pattern 16 is formed by wet etching which progresses isotropically. Accordingly, respective patterns 16 are insulated from one another.

Referring to FIG. 4C, a cross-sectional shape of the pattern formed in the foregoing process will be described. A side surface of the pattern 16 formed by wet etching has a tapered structure. That is, the pattern 16 has a rectangular cross section in which a lower bottom is longer than an upper bottom. Here, a dimension between an upper side edge of the resist 10 and an upper side edge of the pattern 16 will be defined as a2. Meanwhile, a dimension (a thickness) from a lower end to the upper end of the pattern 16 will be defined as t. Then, an etching factor Ef is expressed by (Ef=t/a2).

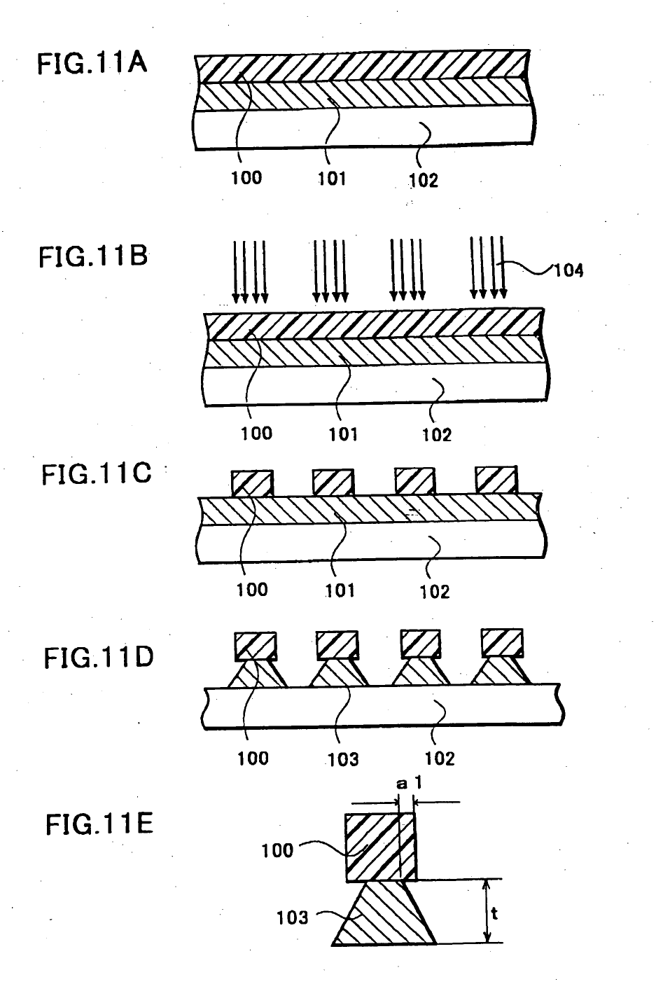

Here, observing the cross section of the resist 10, the region A1 spreading toward the bottom is formed in the lower part thereof. That is, in comparison with the conventional example shown in FIG. 11E, the lower side edge of the resist 10 is protruding outward in the amount equivalent to a width d of the spreading region A1. Thus, the dimension a2 between the upper side edge of the resist and the upper side edge of the pattern 16 becomes smaller in the amount equivalent to the width d of the region A1. Therefore, the etching factor Ef herein is increased in response to the width d. That is, by isotropic etching, a side portion of the pattern 16 is formed into a tapered shape in almost the same degree as the conventional example. However, by protrusion of the region A1, it is possible to bring a relative dimension in a lateral direction between the upper side edge of the resist 10 and the upper side edge of the pattern 16 closer. This can contribute to improvement in the etching factor and thereby to improvement in fine processing.

Improvement in fine processing is usually achieved by finely processing the exposure pattern 15 of the exposure mask 14. To be more precise, when the resist 10 is of the negative type, such fine processing is achieved by narrowing a width L2 of the line in the exposure pattern. Accordingly, promotion of fine processing according to this method involves a large amount of cost for improving a lithography device for the exposure pattern 16. According to the above-described method of the preferred embodiment of the present invention, it is possible to promote fine processing without requiring such a large amount of cost. That is, it is possible to narrow an interval between the patterns 16 without changing the width of the exposure patterns 15 but by forming the region A1 in the lower part of the resist 10. In addition, since a cross-sectional area of the pattern 16 can be increased, it is possible to increase a current capacity.

(Second Embodiment for Describing a Method of Manufacturing a Circuit Device)

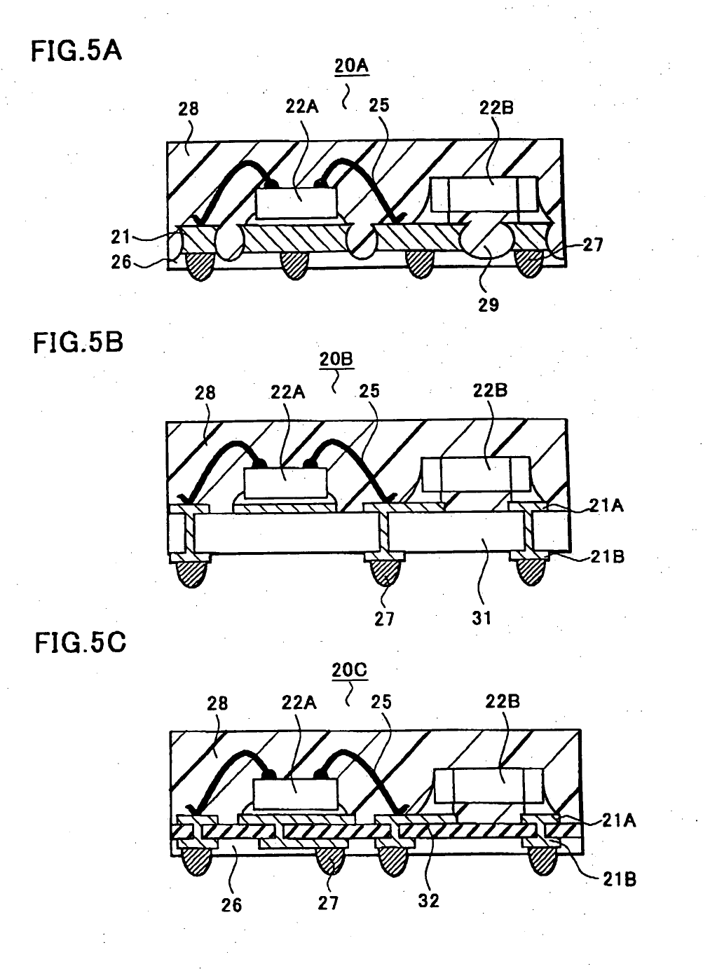

Next, several types of circuit devices manufactured by use of the above-described etching method will be introduced with reference to FIGS. 5A to 5C. Configurations of circuit devices 20A to 20C according to another preferred embodiment of the present invention will be described with reference to FIGS. 5A to 5C. FIG. 5A to FIG. 5C are cross-sectional views of circuit devices of respective modes.

Referring to FIG. 5A, a circuit device 20A of the preferred embodiment of the present invention includes a conductive pattern 21, a circuit element 22 die bonded to the conductive pattern 21 through solder, and an external electrode 27 as connecting means for electrically connecting the conductive pattern 21 to the outside.

The conductive pattern 21 is made of a metal such as copper, and is buried in sealing resin 28 while exposing a rear surface thereof. Meanwhile, respective conductive patterns 21 are electrically insulated by isolation trench 29, and the sealing resin 28 is filled in the isolation trench 29. A side surface of the conductive pattern 21 is formed into a curved shape, thereby enhancing bonding between the conductive pattern 21 and the sealing resin 28.

The isolation trench 29 has a function to electrically insulate the respective conductive patterns 21. Moreover, this isolation trench 29 is formed by the above-described etching method. Accordingly, it is possible to reduce a width relative to a length in a depth direction thereof. That is, it is possible to reduce the interval between the conductive patterns 21. Moreover, the cross-sectional area of the conductive pattern 21 can be increased by widening the width of the conductive pattern 21. Accordingly, it is possible to increase a current capacity thereof.

Here, the circuit element 22 includes a semiconductor element 22A and a chip element 22B. Meanwhile, it is possible to adopt an active element such as an LSI chip, a bare transistor chip or a diode as the circuit element. In addition, it is also possible to adopt a passive element such as a chip resistor or a chip capacitor as the circuit element. With regard to a concrete mounting structure, a rear surface of the semiconductor element 22A is fixed to a pad made of the conductive pattern 21. Further, an electrode on a surface of the semiconductor element 22A and the conductive pattern 21 are electrically connected to each other through thin metal wires 25. Electrodes on both ends of the chip element 22B are fixed to the conductive pattern 21 through solder.

The sealing resin 28 is made of either thermoplastic resin formed by injection molding or thermosetting resin formed by transfer molding. Further, the sealing resin 28 has a function to seal the entire device and a function to mechanically support the entire device. The external electrode 27 is made of solder and is formed on the rear surface of the conductive pattern 21.

Referring to FIG. 5B, a basic configuration of a circuit device 20B shown in the drawing is similar to the above-described circuit device 20A. A difference between these circuit devices is in that the circuit device 20B includes a supporting board 31.

A material having a fine heat radiation property and mechanical strength is adopted as the supporting board 31. Here, it is possible to adopt a metal board, a printed board, a flexible board, a composite board, and the like. Meanwhile, when adopting a board made of a conductive material such as metal, an insulating layer is provided on a surface thereof for insulation from the conductive pattern 21.

A first conductive pattern 21A and a second conductive pattern 21B are formed on a front surface and a rear surface of the supporting board 31. Here, the first conductive pattern 21A and the second conductive pattern 21B are electrically connected to each other while penetrating through the supporting board 31. Meanwhile, the external electrode 27 is formed on the second conductive pattern 21B. Here, the first and second conductive patterns 21A and 21B are also formed by the above-described etching method. Accordingly, it is possible to reduce the interval between the patterns and thereby to promote fine processing.

Referring to FIG. 5C, in a circuit device 20C, the conductive pattern 21 has a multilayer wiring structure. To be more precise, two-layered conductive patterns including the first and second conductive patterns 21A and 21B are laminated with an insulating layer 32, made of resin, interposed therebetween. Here, it is also possible to configure a wiring structure including three or more layers. Further, the first and second conductive patterns 21A and 21B are electrically connected to each other while penetrating the insulating layer 32. Here, the first and second conductive patterns 21A and 21B are also formed by the above-described etching method. Accordingly, it is possible to reduce the interval between the patterns and thereby to promote fine processing.

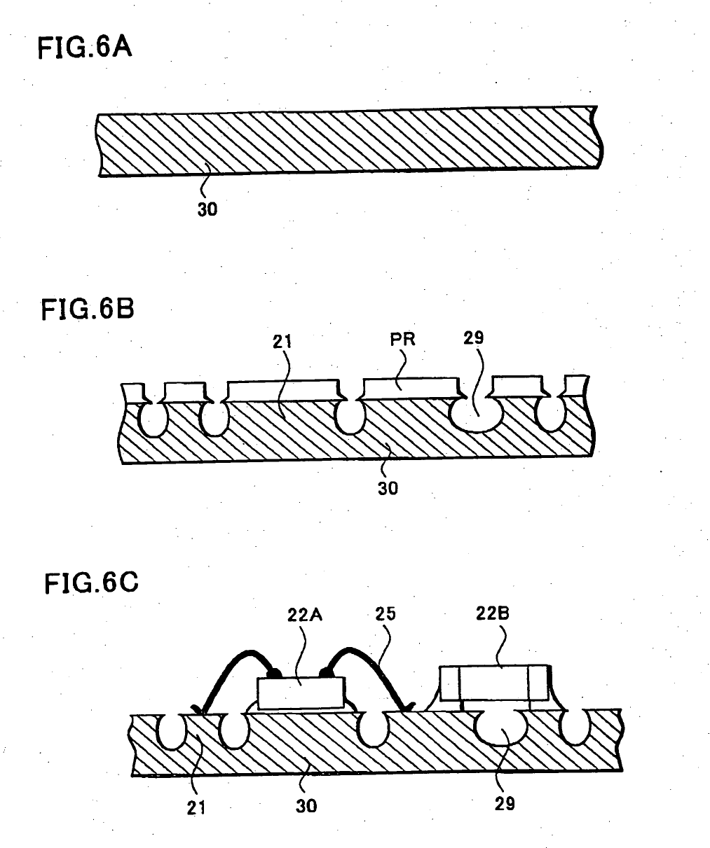

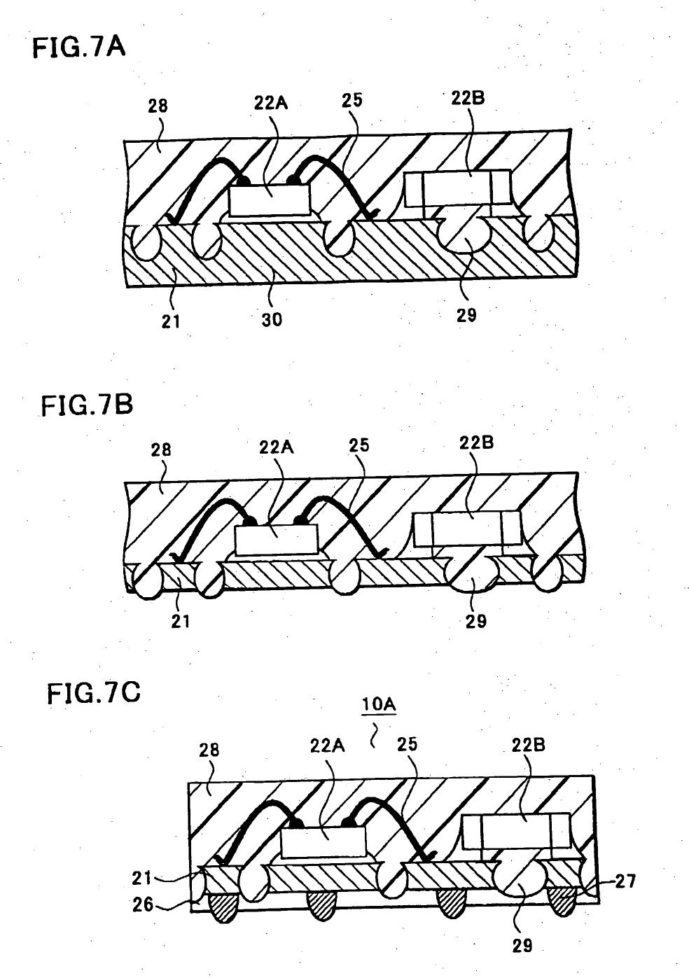

Next, methods of manufacturing the circuit devices having the configuration described in FIGS. 5A to 5C will be explained with reference to FIGS. 6A to 10B. Firstly, a method of manufacturing the circuit device 20A shown in FIG. 5A will be described with reference to FIG. 6A to FIG. 7C.

First of all, referring to FIG. 6A a conductive foil 30 made of a metal such as copper is prepared. Then, as shown in FIG. 6B, an etching resist PR is formed in positions to constitute the conductive pattern. Then, a surface of the conductive foil 30 exposed from the etching resist PR is removed by wet etching, and the isolation trenches 29 are thereby formed. By forming the isolation trenches 29, the respective conductive patterns 21 are formed into convex shapes. Here, since the resist PR has the above-described cross-sectional shape spreading toward the bottom, it is possible to improve the etching factor.

Referring to FIG. 6C, the semiconductor element 22A and the chip element 22B are die bonded to the given conductive pattern 21 by use of a joining material such as solder. Meanwhile, the electrode on the surface of the semiconductor element 22A is electrically connected to the conductive pattern 21 through thin metal wires 25.

Next, referring to FIG. 7A, the sealing resin 28 is formed so as to be filled in the isolation trenches 29 and to cover the circuit element. This sealing resin 28 can be formed by transfer molding using thermosetting resin or by injection molding using thermoplastic resin.

Subsequently, referring to FIG. 7B, the sealing resin 28 filled in the isolation trenches 29 is exposed on the rear surface by removing the conductive foil 30 from all over the rear surface. Then, the respective conductive patterns 21 are electrically insulated from one another. Further, the resist 26 and the external electrodes 27 are formed. In this way, the circuit device as shown in FIG. 7C is finished.

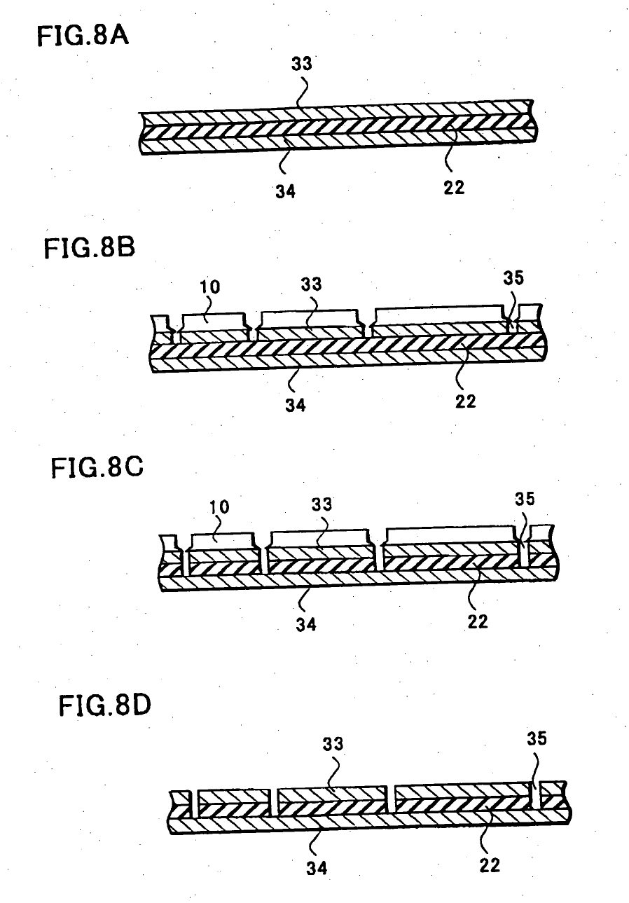

Next, a method of manufacturing the circuit device 20C shown in FIG. 5C will be described with reference to FIG. 8A to FIG. 10B. Firstly, referring to FIG. 8A, a laminated sheet which is formed by laminating a first and second conductive foil 33 and 34 with an insulating layer 22 interposed therebetween is prepared.

Next, referring to FIG. 8B, through holes 35 are formed by selectively removing the first conductive foil 33. This can be achieved by wet etching using the resist 10. The resist 10 to be used herein is formed by the above-described etching method, and has the cross-sectional shape spreading toward the bottom. Therefore, it is possible to form finer through holes 35 and thereby to reduce the area occupied by the through holes 35. Accordingly, it is possible to use the remaining region as a region for forming the conductive pattern, and is thereby possible to improve wiring density. In addition, it is possible to achieve downsizing of the entire device.

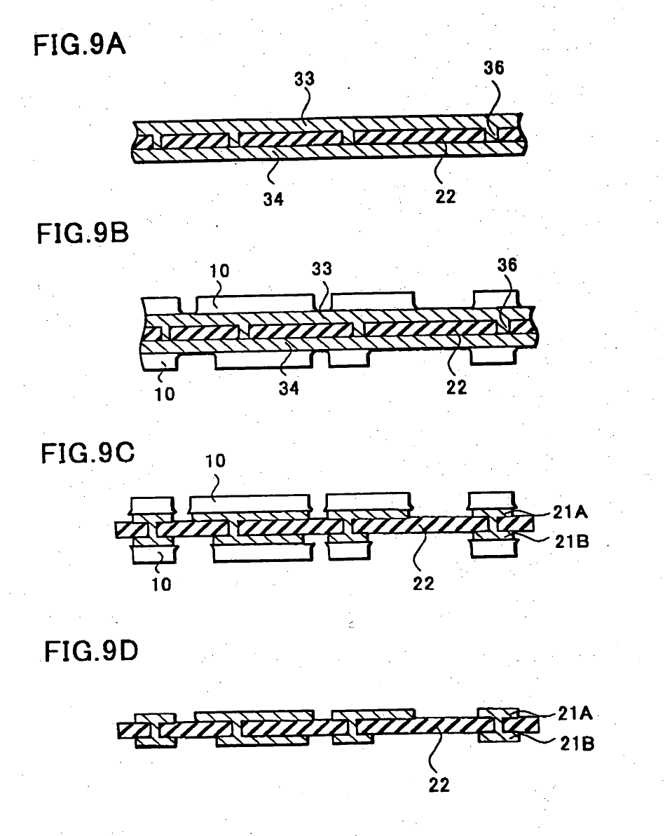

Subsequently, referring to FIG. 8C, the through holes 35 are allowed to reach a surface of the second conductive foil 34 by removing the insulating layer 22 at a lower part of the through holes 35. This insulating layer 22 may be removed by use of a carbon dioxide gas laser. Thereafter, the cross-sectional structure as shown in FIG. 8D is obtained by peeling the resist 10 off. Then, referring to FIG. 9A, connection parts 36 are formed inside the through holes 35 by forming a plated film made of a metal such as copper, whereby the first conductive foil 33 is electrically connected to the second conductive foil 34.

Thereafter, referring to FIG. 9B, for the purpose of etching the first and second conductive foils 33 and 34, the etching resist 10 is selectively formed on the surface of the both conductive foils. This resist 10 is formed by the method described in the first embodiment, and therefore has the cross-sectional shape spreading toward the bottom.

Subsequently, referring to FIG. 9C, the first and second conductive patterns 21A and 21B are formed by wet etching. As described above, since the resist 10 has the cross-sectional shape spreading toward the bottom, it is possible to form fine conductive patterns. Then, the cross-sectional shape as shown in FIG. 9D is obtained by removing the resist 10.

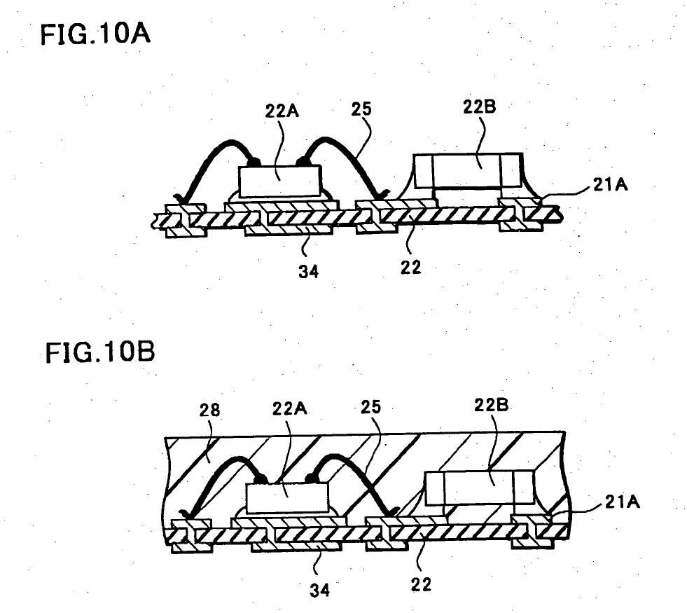

Next, referring to FIG. 10A, the semiconductor element 22A and the chip element 22B are die bonded to the first conductive pattern 21A. Then, referring to FIG. 10B, the sealing resin 28 is formed so as to cover the semiconductor element 22A and the chip element 22B. In addition, the circuit device as shown in FIG. 5C is finished by providing a treatment on the rear surface.

According to the preferred embodiments of the present invention, a resist having a cross-sectional shape spreading toward a bottom is formed, and an etching target material is wet-etched by using this resist as an etching mask. Accordingly, it is possible to improve an etching factor. In addition, it is possible to achieve fine processing of a conductive pattern to be formed by etching.

1. An etching method comprising:
forming an etching resist on a surface of an etching target material;
forming a remaining region having a cross section in which a lower part is greater than an upper part by subjecting the etching resist to selective exposure using an exposure mask and thereby selectively transforming the etching resist;
removing the etching resist other than the remaining region by use of a solution; and
etching the etching target material by use of the remaining region as a mask.

2. The etching method according to claim 1,
wherein the etching resist is a negative resist, and
the lower part of the cross section of the remaining region becomes greater than the upper part thereof by irradiating a region of the negative resist corresponding to the remaining region with a light beam and by allowing the light beam to pass through the negative resist and to be reflected by a surface of the etching target material.

3. The etching method according to claim 1,
wherein the etching resist is a positive resist, and
the lower part of the cross section of the remaining region becomes greater than the upper part thereof by irradiating a removing region of the positive resist with a light beam and by allowing the light beam radiating on a peripheral portion of the removing region to be attenuated in mid-course of the etching resist.

4. A method of manufacturing a circuit device comprising:
preparing a conductive foil;
forming an etching resist on a surface of the conductive foil;
forming a remaining region having a cross section in which a lower part is greater than an upper part by subjecting the etching resist to selective exposure using an exposure mask and thereby selectively transforming the etching resist;
removing the etching resist other than the remaining region by use of a solution;
forming a conductive pattern by etching the conductive foil using the remaining region as a mask;
disposing a circuit element on the conductive pattern; and
forming a sealing resin to cover the circuit element.

5. The method of manufacturing a circuit device according to claim 4,
wherein an isolation trench shallower than the conductive foil is formed between the conductive patterns by etching,
the sealing resin is filled in the isolation trench in a step of forming the sealing resin, and
the method further includes removing a rear surface of the conductive foil until the sealing resin filled in the isolation trench is exposed.

6. The method of manufacturing a circuit device according to claim 4,
wherein the etching resist is a negative resist, and
the lower part of the cross section of the remaining region becomes greater than the upper part thereof by irradiating a region of the negative resist corresponding to the remaining region with a light beam and by allowing the light beam to pass through the negative resist and to be reflected by a surface of the etching target material.

7. The method of manufacturing a circuit device according to claim 4,
wherein the etching resist is a positive resist, and
the lower part of the cross section of the remaining region becomes greater than the upper part thereof by irradiating a removing region of the positive resist with a light beam and by allowing the light beam radiating on a peripheral portion of the removing region to be attenuated in mid-course of the etching resist.

8. The method of manufacturing a circuit device according to claim 4,
wherein the conductive foil includes a plurality of layers of conductive foil laminated with an insulating layer interposed therebetween, and
the conductive patterns are formed in multiple layers.
